(19) United States
(12) Patent Application Publication
(10) Pub. No.: US 2026/0282692 A1
(43) Pub. Date: Sep. 17, 2026

(54) ORGANIC ELECTROLUMINESCENT DEVICES

(71) Applicant: Universal Display Corporation, Ewing, NJ (US)

(72) Inventors: Michael Hack, Carmel, CA (US); Michael Stuart Weaver, Princeton, NJ (US)

(21) Appl. No.: 19/561,668

(22) Filed: Mar. 10, 2026

Related U.S. Application Data
(60) Provisional application No. 63/769,810, filed on Mar. 11, 2025.

(51) Int. Cl. H10K 59/35; H10K 50/115; H10K 50/19; H10K 59/38; H10K 59/65; H10K 101/20

(52) U.S. Cl. CPC H10K 59/35; H10K 50/115; H10K 50/19; H10K 59/38; H10K 59/65; H10K 2101/20

(57) ABSTRACT

Embodiments of the disclosed subject matter provide a device having one or more pixels. A first pixel of the one or more pixels may include a first sub-pixel and a second sub-pixel. The first sub-pixel of the first pixel may be at least 30% transparent across a portion of a wavelength spectrum, where the wavelength spectrum is from 400 nm to 1500 nm. The second sub-pixel of the first pixel may be less than 10% transparent across the portion of the wavelength spectrum.

### CROSS-REFERENCE TO RELATED APPLICATIONS

This application claims priority to U.S. Patent Application Ser. No. 63/769,810, filed Mar. 11, 2025, the entire contents of which are incorporated herein by reference.

### FIELD

The present invention relates to devices and techniques for fabricating organic emissive devices, such as organic light emitting diodes, that have both transparent and non-transparent sub-pixels, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a device that is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more devices selected from a consumer product, an electronic component module, and/or a lighting panel.

According to an embodiment, a device may have one or more pixels. A first pixel of the one or more pixels may include a first sub-pixel and a second sub-pixel. The first sub-pixel of the first pixel may be at least 30% transparent across a portion of a wavelength spectrum, where the wavelength spectrum is from 400 nm to 1500 nm. The second sub-pixel of the first pixel may be less than 10% transparent across the portion of the wavelength spectrum.

The devices of the embodiments described above may be a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, an optical communication device, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example pixel arrangement of a device with three or more sub-pixels having one or more organic emissive layers, where one sub-pixel has non-transparent electrodes, the other sub-pixel has one transparent electrode, and one of the sub-pixels may be a cavity according to an embodiment of the disclosed subject matter.

FIG. 4 shows an example pixel arrangement of a device with three or more sub-pixels having one or more organic emissive layers, where two of the sub-pixels may each have one non-transparent electrode, one of the sub-pixels may have transparent electrodes, and where two of the sub-pixels may have a cavity according to an embodiment of the disclosed subject matter.

FIG. 5 shows an example pixel arrangement similar to the one shown in FIG. 3, but where one sub-pixel has two non-transparent electrodes (e.g., a plasmonic sub-pixel), the other sub-pixels has one transparent electrode, and one of the sub-pixels may be a cavity according to an embodiment of the disclosed subject matter.

FIG. 6 shows an example pixel arrangement similar to the one shown in FIG. 4, but one sub-pixel may have two non-transparent electrodes (e.g., a plasmonic sub-pixel), another sub-pixel may have one non-transparent electrode according to an embodiment of the disclosed subject matter.

FIG. 7 shows an example pixel arrangement similar to those shown in FIGS. 4 and 7, but two sub-pixels may each have two non-transparent electrodes, and another sub-pixel may have transparent electrodes according to an embodiment of the disclosed subject matter.

FIG. 8 shows an example stacked pixel arrangement, where one group of stacked sub-pixels may have two non-transparent electrodes, and two other groups of stacked sub-pixels may have transparent electrodes according to an embodiment of the disclosed subject matter.

FIG. 9 shows an example stacked pixel arrangement, where two groups of stacked sub-pixels may each have one non-transparent electrode, and another group of stacked sub-pixels may have transparent electrodes according to an embodiment of the disclosed subject matter.

FIG. 10 shows an example stacked pixel arrangement, where one group of stacked sub-pixels may each have two non-transparent electrodes, and two other groups of stacked sub-pixels may have transparent electrodes according to an embodiment of the disclosed subject matter.

FIG. 11 shows an example stacked pixel arrangement, where one group of stacked sub-pixels may each have two non-transparent electrodes, one group of stacked sub-pixels may have one non-transparent electrode, and another group of stacked sub-pixels may have transparent electrodes according to an embodiment of the disclosed subject matter.

FIG. 12 shows an example layout, which allows for one section of a display to be driven as a passive matrix display to increase transparency including an optional dedicated passive matrix (PM) shift register/scan driver and a passive matrix data driver chip to provide current sourcing for PM drive according to embodiments of the disclosed subject matter.

FIGS. 13A-13B show an example of a layout for a RGB1B2 (red, green, light blue, deep blue) display where each deep blue (B2) cavity or plasmonic sub-pixel may be shared amongst 4 pixels, and the other 3 blue sub-pixels may be transparent and may be light blue, according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

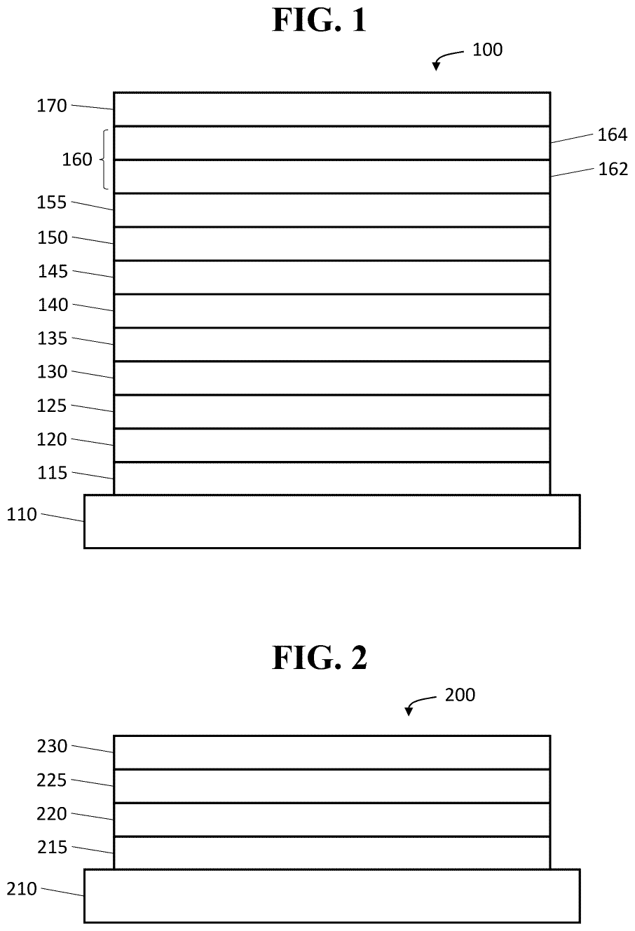

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

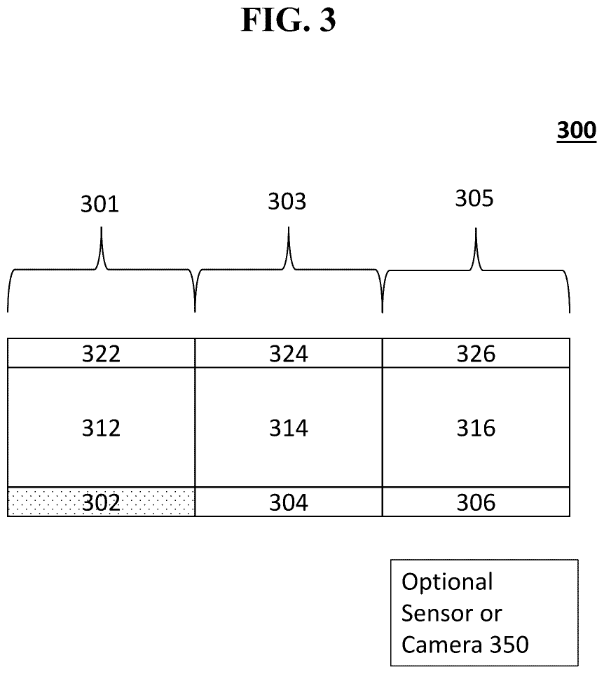

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant, as disclosed in U.S. Pat. No. 9,960,386 and incorporated by reference in its entirety. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered or extracted as photons to free space. In other embodiments, the energy is scattered or extracted from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric spacer layers can be disposed between the enhancement layer and the outcoupling layer. The plasmonic stack may include a dielectric spacer material (i.e., a dielectric spacer layer) having a refractive index selected based on a color of light emitted by the organic emissive material. In an embodiment, the dielectric spacer material (i.e., dielectric spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of either electrode, outside of the plasmonic stack. In yet another embodiment, the dielectric spacer material may be located between the enhancement layer and the outcoupling layer or may be integrated within the outcoupling layer. In some embodiments, the dielectric spacer layer may be found only in a plasmonic stack sub-pixel, only in a non-plasmonic stack sub-pixel or in both. Examples of material suitable for use in dielectric spacer layers include dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, an optical communication device, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C. Additionally, devices fabricated in accordance with embodiments of the invention may be incorporated into optical communication devices.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent over at least a portion of the wavelength spectrum. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Embodiments of the disclosed subject matter may provide an OLED display that has both high transparency, high efficiency, and extended lifetime. In some embodiments, the display may be transparent, and sensors, cameras, or the like may be disposed under the display. This arrangement may allow as much light as possible to reach these devices.

It may be difficult to have displays with high efficiency deep blue without using a cavity, blue sub-pixels in embodiments of the disclosed subject matter may have a cavity structure. Green sub-pixels may have a cavity to achieve a very saturated green (e.g., Rec 2020 standard), but may not need a cavity structure in order to be configured for the DCIP3 color gamut. In some embodiments, color altering layers (e.g., color filters and the like) may be used to produce at least green light. In some embodiments of the disclosed subject matter, green sub-pixels may have a cavity arrangement, and/or may be transparent.

In some embodiments, a color altering layer may be used with a device to output blue light, but there may be losses in efficiency. In some embodiments, the display transmission may be sufficient without blue sub-pixels being transparent sub-pixels. In some embodiments, the density of blue sub-pixels may not need to be as high as the red sub-pixels and/or the green sub-pixels due to the low spatial response of the human eyes, where there is lower S cone density in the retina.

Red light may be the easiest color to achieve display performance without a cavity, so sub-pixels that are configured to output red light may be transparent. Embodiments of the disclosed subject matter may provide a display that may have a mixture of cavity sub-pixels and transparent sub-pixels.

Embodiments of the disclosed subject matter may balance transparency, efficiency, and/or color point (e.g., a specific coordinate within a color space that defines a particular color on the screen) in a device. Currently, the transparency of displays does not allow for easy embedding of sensors, cameras, and the like under the display. Moreover, current arrangements do not allow as much light as possible to reach such sensors, cameras, and the like.

Embodiments of the disclosed subject matter may improve on current arrangements, as they may have at least one sub-pixel in a pixel that has a cavity arrangement. In some embodiments, a sub-pixel may be a blue sub-pixel that may have a cavity arrangement, and the blue sub-pixel may be a deep blue sub-pixel.

In an embodiment, at least one sub-pixel in a pixel of a display may be fully transparent across at least a portion of the wavelength spectrum to provide reasonable display transparency. In an embodiment, this pixel may be a sub-pixel which may be configured to output red light and/or yellow light.

One sub-pixel of a pixel may be configured to have a cavity arrangement or may be fully transparent, depending on a desired color saturation and/or color point. This sub-pixel may be configured to output green light, and may have a cavity arrangement that is configured to output a saturated green light (e.g., Rec 2020 standard). In an embodiment, one sub-pixel of a pixel may be configured to have a cavity arrangement or may be fully transparent, and the sub-pixel may be configured to output yellow light, cyan light, and/or red light. In some embodiments, this sub-pixel may not need a cavity to be configured to generate a DCIP3 color gamut, and color altering layers may be added to enhance color saturation. In some embodiments, yellow sub-pixels may be used in a RGBY (red, green blue, yellow) display where a yellow (Y) sub-pixel may be either a transparent sub-pixel or a cavity sub-pixel.

Displays have been proposed that have cavity blue sub-pixels and Lambertian bottom emission for red and green sub-pixels, with the goal of improving viewing angle. Embodiments of the disclosed subject matter may include a cavity blue sub-pixel combined with a transparent green sub-pixel and a transparent red sub-pixel. The cavity arrangement may be used to provide improved efficacy perpendicular to the display surface and color point. In some embodiments, the green sub-pixel may either have a cavity or may be transparent. For a transparent sub-pixel, both electrodes of the sub-pixel may be transparent or semi-transparent.

In an embodiment, a device may have one or more pixels, where a first pixel may include a first sub-pixel and a second sub-pixel. The first sub-pixel of the first pixel may be at least 30% transparent across at least a portion of a wavelength spectrum, where the wavelength spectrum is from 400 nm to 1500 nm. The second sub-pixel of the first pixel may be less than 10% transparent across at least a portion of the wavelength spectrum.

In an embodiment, transparency of the display and the transparency of the blue sub-pixels may be improved by using a B1B2 arrangement, which may use select blue sub-pixels to be non-transparent (e.g., cavity sub-pixels or plasmonic sub-pixels) to provide deep blue B2, and the remaining pixels may be transparent and provide light blue B1. In an embodiment of the B1B2 arrangement, only 1/N pixels may need a deep blue (B2) sub-pixel, where N is an even integer greater or equal to 2. In prior display arrangement, B1 sub-pixels were disposed in every pixel, and then shared B2 sub-pixels amongst multiple pixels. In embodiments of the disclosed subject matter, there may be only one blue subpixel per pixel, either transparent light blue or non-transparent deep blue. For pixels rendering images requiring a lighter blue than the light blue sub-pixel, then all blue sub-pixels may be used. To render blue colors more saturated than the light blue sub-pixel color, only deep blue sub-pixels may be used. A similar approach could be used for pixel designs where there are two types of red sub-pixels, light red and deep red or else pixel designs where there are two types of green sub-pixels, light green and deep green.

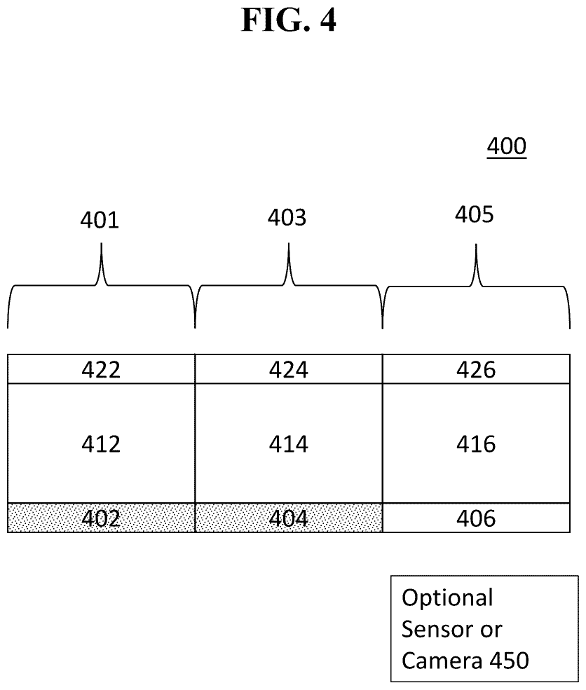

FIG. 3 shows an example pixel arrangement 300 of a device with three or more sub-pixels (e.g., sub-pixels, 301, 303, and/or 305) having one or more organic emissive layers, where one sub-pixel has non-transparent electrodes, the other sub-pixels have transparent electrodes an organic light emitting device, and one of the sub-pixels may be a cavity according to an embodiment of the disclosed subject matter. One sub-pixel 301 may include organic layer 312 that is disposed between non-transparent electrodes 302 and transparent electrode 322. In one embodiment, the sub-pixel 301 may be configured to output blue light. Another sub-pixel 303 may include organic layer 314 that is disposed between transparent electrodes 304 and 324. Another sub-pixel 305 may include organic layer 316 that is disposed between transparent electrodes 306 and 326. In one embodiment, the sub-pixel 303 and the sub-pixel 305 may be configured to output green light and/or red light. In some embodiments, the organic layers 312, 314, and/or 316 may include one layer and/or a plurality of layers. In some embodiments, a sensor or camera 350 may be disposed below a transparent sub-pixel, such as sub-pixel 303 and/or sub-pixel 305.

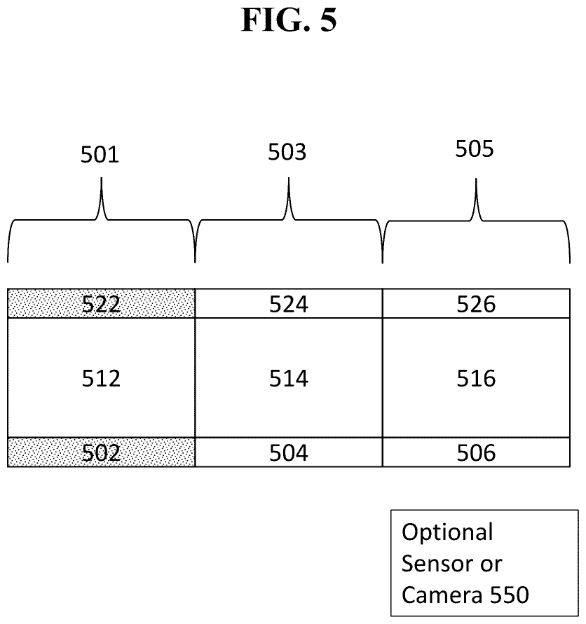

FIG. 4 shows an example pixel arrangement 400 of a device with three or more sub-pixels (e.g., sub-pixels 401, 403, and/or 405) having one or more organic emissive layers, where two of the sub-pixels may have non-transparent electrodes, one of the sub-pixels may have transparent electrodes, and where two of the sub-pixels may have a cavity according to an embodiment of the disclosed subject matter. Sub-pixel 401 may include organic layer 412 may be disposed between non-transparent electrodes 402 and transparent electrode 422. Sub-pixel 403 may include organic layer 414 that is disposed between non-transparent electrode 404 and transparent electrode 424. In some embodiments, the sub-pixel 401 and the sub-pixel 403 may be configured to have cavities. In some embodiments, the sub-pixel 401 may be configured to output blue light, and the sub-pixel 403 may be configured to output green light. Sub-pixel 405 may include organic layer 416 disposed between transparent electrodes 406 and 426. In some embodiments, the sub-pixel 405 may be configured to output red light. In some embodiments, a sensor or camera 450 may be disposed below a transparent sub-pixel, such as sub-pixel 405.

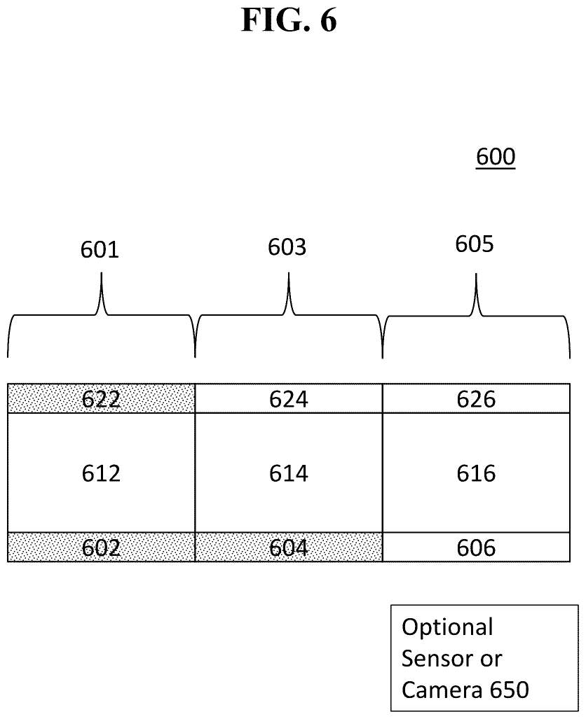

FIG. 5 shows an example pixel arrangement 500 of a device with three or more sub-pixels (e.g., sub-pixels, 501, 503, and/or 505) having one or more organic emissive layers, where one sub-pixel has non-transparent electrodes, the other sub-pixels have transparent electrodes an organic light emitting device, and one of the sub-pixels may be a cavity according to an embodiment of the disclosed subject matter. One sub-pixel 501 may include organic layer 512 that is disposed between non-transparent electrodes 502 and 522. In one embodiment, the sub-pixel 501 may be configured to output blue light. Another sub-pixel 503 may include organic layer 514 that is disposed between transparent electrodes 504 and 524. Another sub-pixel 305 may include organic layer 516 that is disposed between transparent electrodes 506 and 526. In one embodiment, the sub-pixel 503 and the sub-pixel 505 may be configured to output green light and/or red light. In some embodiments, the organic layers 512, 514, and/or 516 may include one layer and/or a plurality of layers. In some embodiments, a sensor or camera 550 may be disposed below a transparent sub-pixel, such as sub-pixel 503 and/or sub-pixel 505.

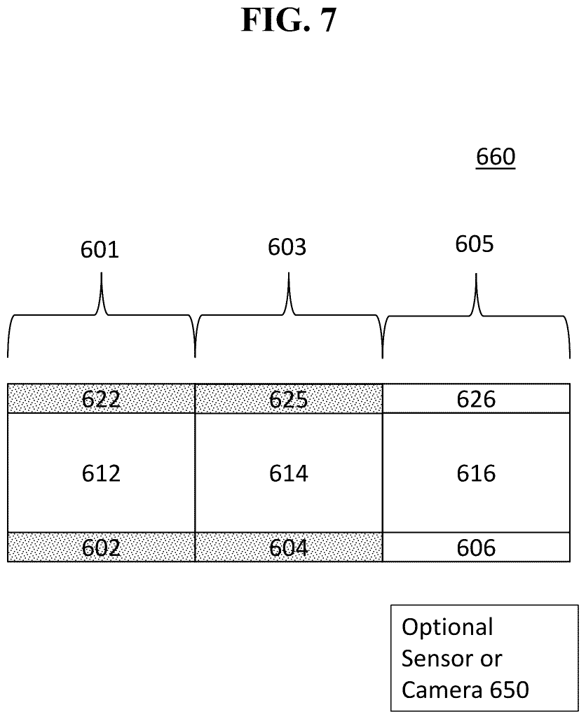

FIG. 6 shows an example pixel arrangement 600 of a device with three or more sub-pixels (e.g., sub-pixels 601, 603, and/or 605) having one or more organic emissive layers, where two of the sub-pixels may have at least one non-transparent electrode, one of the sub-pixels may have transparent electrodes, and where two of the sub-pixels may have a cavity according to an embodiment of the disclosed subject matter. Sub-pixel 601 may include organic layer 612 may be disposed between non-transparent electrodes 602 and 622. Sub-pixel 603 may include organic layer 614 that is disposed between non-transparent electrode 604 and transparent electrode 624. In some embodiments, the sub-pixel 601 and the sub-pixel 603 may be configured to have cavities. In some embodiments, the sub-pixel 601 may be configured to output blue light, and the sub-pixel 603 may be configured to output green light. Sub-pixel 605 may include organic layer 616 disposed between transparent electrodes 606 and 626. In some embodiments, the sub-pixel 605 may be configured to output red light. In some embodiments, a sensor or camera 650 may be disposed below a transparent sub-pixel, such as sub-pixel 605.

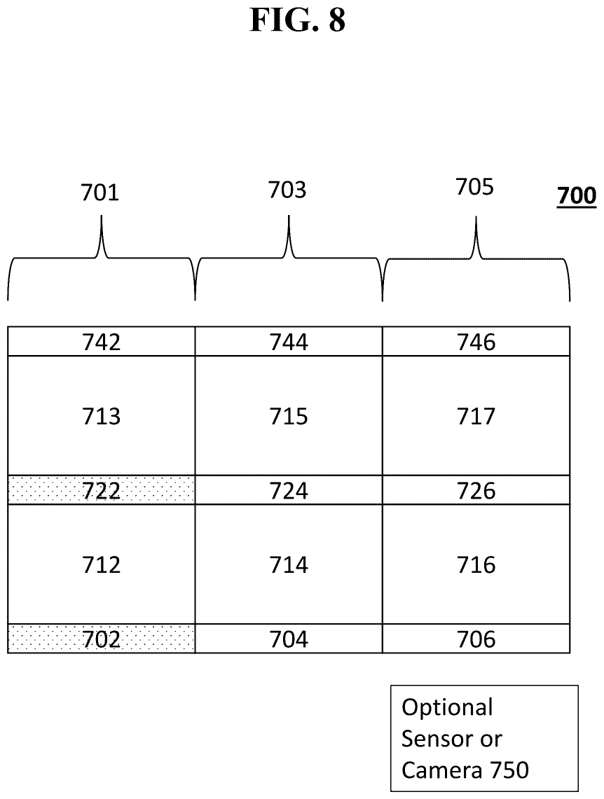

The example pixel arrangement 660 shown in FIG. 7 is similar to the pixel arrangement 600 shown in FIG. 6, but the sub-pixel 603 in pixel arrangement 660 may include organic layer 614 that is disposed between non-transparent electrodes 604 and 625.

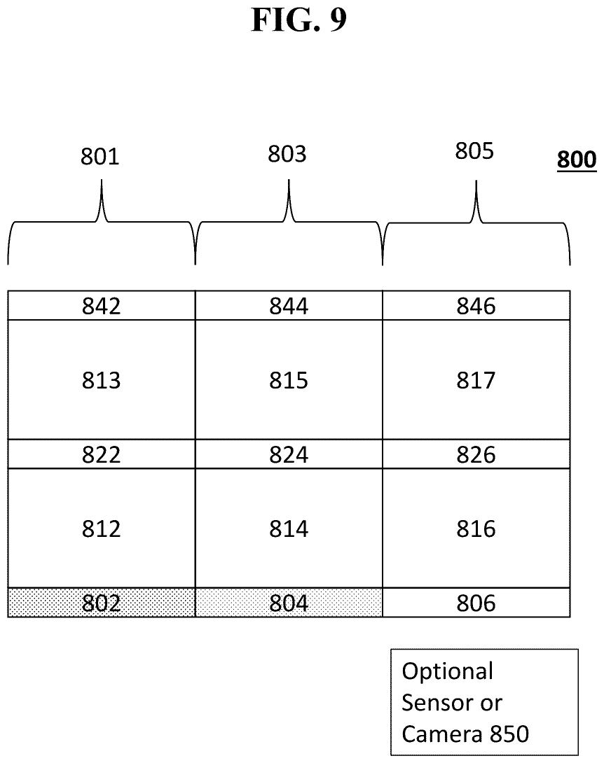

FIG. 8 shows an example pixel arrangement 700, which includes stacked sub-pixel groups 701, 703, and 705. The first stacked sub-pixel group 701 may include emissive layer 712 disposed between non-transparent electrodes 702 and 722, and emissive layer 713 disposed between non-transparent electrode 722 and transparent electrode 742. A second stacked sub-pixel group 703 may include emissive layer 714 disposed between transparent electrodes 704 and 724, and emissive layer 715 disposed between transparent electrodes 724 and 744. A third stacked sub-pixel group 705 may include an emissive layer 716 disposed between transparent electrodes 706 and 726, and emissive layer 717 disposed between transparent electrodes 726 and 746. In some embodiments, a sensor or camera 750 may be disposed below a transparent stacked sub-pixel group, such as second stacked sub-pixel group 703 or third stacked sub-pixel group 705.

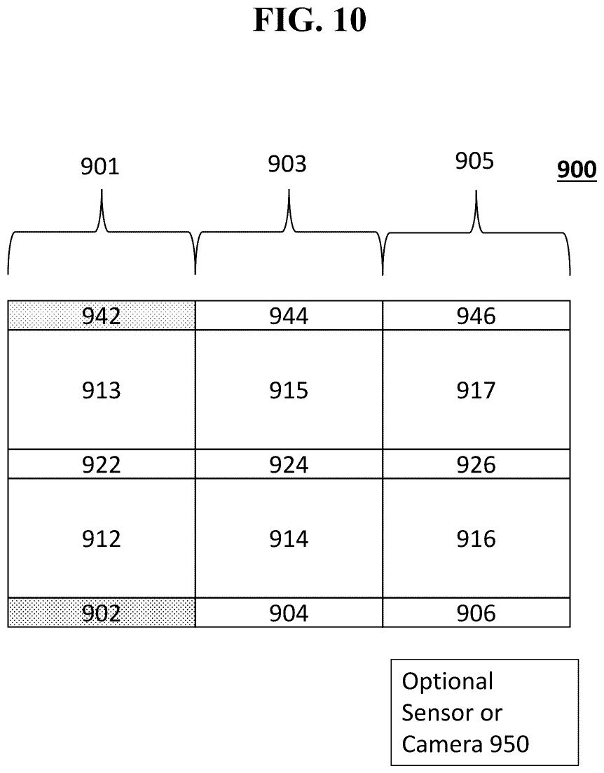

FIG. 9 shows an example pixel arrangement 800, which includes stacked sub-pixel groups 801, 803, and 805. The first stacked sub-pixel group 801 may include emissive layer 812 disposed between non-transparent electrode 802 and transparent electrode 822, and emissive layer 813 disposed between transparent electrodes 822 and 842. A second stacked sub-pixel group 803 may include emissive layer 814 disposed between non-transparent electrode 804 and transparent electrode 824, and emissive layer 815 disposed between transparent electrodes 824 and 844. A third stacked sub-pixel 805 group may include an emissive layer 816 disposed between transparent electrodes 806 and 826, and emissive layer 817 disposed between transparent electrodes 826 and 846. In some embodiments, a sensor or camera 850 may be disposed below a transparent stacked sub-pixel group, such as third stacked sub-pixel group 805.

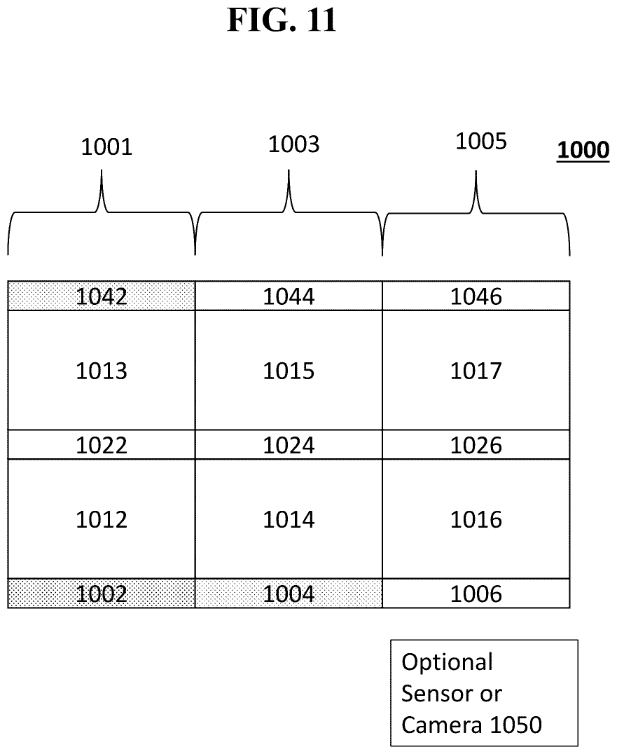

FIG. 10 shows an example pixel arrangement 900, which includes stacked sub-pixel groups 901, 903, and 905. The first stacked sub-pixel group 901 may include emissive layer 912 disposed between non-transparent electrode 902 and transparent electrode 922, and emissive layer 913 disposed between transparent electrode 922 and non-transparent electrode 942. The transparent electrode 922 of the first stacked sub-pixel group may allow for light to exit this sub-pixel group. A second stacked sub-pixel group 903 may include emissive layer 914 disposed between transparent electrodes 904 and 924, and emissive layer 915 disposed between transparent electrodes 924 and 944. A third stacked sub-pixel group 905 may include an emissive layer 916 disposed between transparent electrodes 906 and 926, and emissive layer 917 disposed between transparent electrodes 926 and 946. In some embodiments, a sensor or camera 950 may be disposed below a transparent stacked sub-pixel group, such as second stacked sub-pixel group 903 or third stacked sub-pixel group 905.

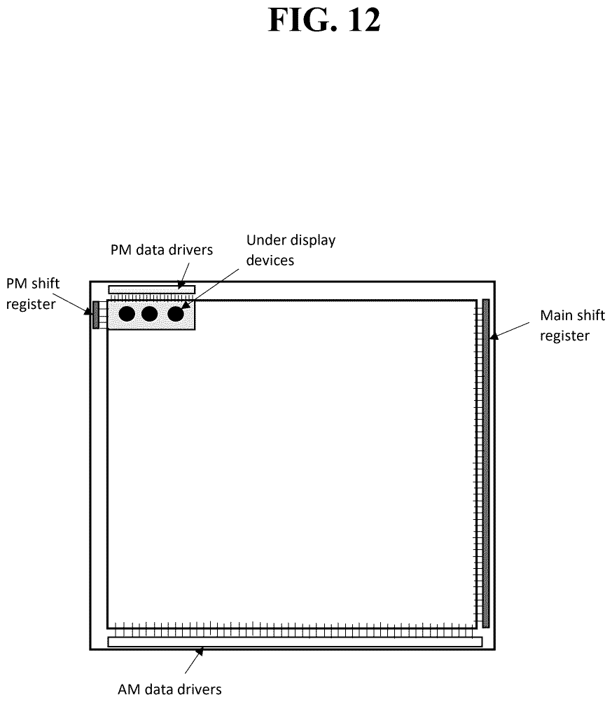

FIG. 11 shows an example pixel arrangement 1000, which includes stacked sub-pixel groups 1001, 1003, and 1005. The first stacked sub-pixel group 1001 may include emissive layer 1012 disposed between non-transparent electrode 1002 and transparent electrode 1022, and emissive layer 1013 disposed between transparent electrode 1022 and non-transparent electrode 1042. The transparent electrode 1022 of the first stacked sub-pixel group may allow for light to exit this sub-pixel group. A second stacked sub-pixel group 1003 may include emissive layer 1014 disposed between non-transparent electrode 1004 and transparent electrode 1024, and emissive layer 1015 disposed between transparent electrodes 1024 and 1044. A third stacked sub-pixel group 1005 may include an emissive layer 1016 disposed between transparent electrodes 1006 and 1026, and emissive layer 1017 disposed between transparent electrodes 1026 and 1046. In some embodiments, a sensor or camera 1050 may be disposed below a transparent stacked sub-pixel group, such as third stacked sub-pixel group 1005.

Embodiments of the disclosed subject matter shown in FIGS. 3-12 may include a device having one or more pixels (e.g., a device having pixel arrangement 300, 400, 500, 600, 660, 700, 800, 900, and 1000), with a first pixel of the one or more pixels having a first sub-pixel, where the first sub-pixel is at least 30% transparent across a portion of a wavelength spectrum that may be 400 nm to 1500 nm. The device may include a second sub-pixel of the first pixel, where the second subpixel is less than 10% transparent across the portion of the wavelength spectrum. For example, as shown in FIG. 3, the first sub-pixel of the first pixel may be sub-pixel 303 or 305, and the second sub-pixel of the first pixel may be sub-pixel 301. In FIG. 4, the first sub-pixel of the first pixel may be sub-pixel 405, and the second sub-pixel of the first pixel may be sub-pixel 401 or sub-pixel 403. In FIG. 5, the first sub-pixel of the first pixel may be sub-pixel 503 or 505, and the second sub-pixel of the first pixel may be sub-pixel 501. In FIG. 6, the first sub-pixel of the first pixel may be sub-pixel 605, and the second sub-pixel of the first pixel may be sub-pixel 601 or 603. In FIG. 7, the first sub-pixel of the first pixel may be sub-pixel 605, and the second sub-pixel of the first pixel may be sub-pixel 601 or 603. In FIG. 8, the first sub-pixel of the first pixel may be sub-pixel group 703 or 705, and the second sub-pixel of the first pixel may be sub-pixel group 701. In FIG. 9, the first sub-pixel of the first pixel may be sub-pixel group 805, and the second sub-pixel of the first pixel may be sub-pixel group 801 or 803. In FIG. 10, the first sub-pixel of the first pixel may be sub-pixel group 903 or 905, and the second sub-pixel of the first pixel may be sub-pixel group 901. In FIG. 11, the first sub-pixel of the first pixel may be sub-pixel group 1005, and the second sub-pixel of the first pixel may be sub-pixel group 1001 or 1003. In some embodiments, the first sub-pixel of the first pixel may be configured to output green light, yellow light, and/or red light.

In some embodiments, the first sub-pixel of the first pixel may be disposed over a sensor and configured to allow a range of wavelengths of light to be transmitted for which a sensor is configured for. For example, the first sub-pixel of the first pixel may be sub-pixel 305 that is disposed over the sensor or camera 350 shown in FIG. 3. In FIG. 4, the first sub-pixel of the first pixel may be sub-pixel 405 that is disposed over the sensor or camera 450. In FIG. 5, the first sub-pixel of the first pixel may be sub-pixel 505 that is disposed over the sensor or camera 550. In FIGS. 6-7, the first sub-pixel of the first pixel may be sub-pixel 605 that is disposed over the sensor or camera 650. In FIG. 8, the first sub-pixel of the first pixel may be sub-pixel group 705 that is disposed over the sensor or camera 750. In FIG. 9, the first sub-pixel of the first pixel may be sub-pixel group 805 that is disposed over the sensor or camera 850. In FIG. 10, the first sub-pixel of the first pixel may be sub-pixel group 905 that is disposed over the sensor or camera 950. In FIG. 11, the first sub-pixel of the first pixel may be sub-pixel group 1005 that is disposed over the sensor or camera 1050.

In some embodiments, the transparency of the first sub-pixel of the first pixel may be configured to allow greater than 30%, greater than 40%, greater than 50%, greater than 60%, greater than 70%, greater than 80%, and/or greater than 90% of a portion of to pass through the first sub-pixel. In an embodiment, the portion of the wavelength spectrum may be in the range of 400 nm to 1500 nm. In an embodiment, the wavelength spectrum may be in the range of 400 nm to 700 nm. In an embodiment, the portion of the wavelength spectrum may be 450 nm to 650 nm. In an embodiment, the portion of the wavelength spectrum may be 500 nm to 650 nm. In an embodiment, the portion of the wavelength spectrum may be two sub-groups of wavelength ranges of visible light. For example, a first sub-group may be 500 nm to 550 nm and the second sub-group may be 600 nm to 650 nm. In an embodiment, the transparency of the first sub-pixel of the first pixel may be configured to allow greater than 30%, greater than 40%, greater than 50%, greater than 60%, greater than 70%, greater than 80%, and/or greater than 90% as an average transparency over at least a portion of the wavelength spectrum (e.g., the range of 400 nm to 1500 nm, the visible light range of 400 nm to 700 nm, or the like). For example, the first sub-pixel of the first pixel may be greater than 90% transparent over 501 nm to 600 nm and greater than 10% transparent over 601 nm to 700 nm, and therefore has an average transparency of greater than 50% over the portion of visible light in the range of 501 nm to 700 nm.

In an embodiment, first sub-pixel of the first pixel may be configured to output red light, orange light, yellow light, and/or green light. In an embodiment, the second sub-pixel of the first pixel may be configured to output light blue light and/or deep blue light.

The transparency of the second sub-pixel of the first pixel may be configured to allow less than 10%, less than 9%, less than 8%, less than 7%, less than 6%, less than 5%, less than 4%, less than 3%, less than 2%, and/or less than 1% of a portion of a wavelength spectrum to pass through the second sub-pixel. In an embodiment, the portion of the wavelength spectrum may be in the range of 400 nm to 1500 nm. In an embodiment, the portion of the wavelength spectrum may be in the range of 400 nm to 700 nm. In an embodiment, the portion of the wavelength spectrum may be in the range of 450 nm to 650 nm. In embodiment, the portion of the wavelength spectrum may be in the range of 500 nm to 650 nm. In an embodiment, the portion of the wavelength spectrum may be two sub-groups of wavelength ranges of visible light. For example, a first sub-group may be 500 nm to 550 nm and the second sub-group may be 600 nm to 650 nm. In an embodiment, the transparency of the second sub-pixel of the first pixel may be configured to allow less than 10%, less than 9%, less than 8%, less than 7%, less than 6%, less than 5%, less than 4%, less than 3%, less than 2%, and/or less than 1% of a portion of the wavelength spectrum to pass through the second sub-pixel. For example, the second sub-pixel of the first pixel may be less than 9% transparent over 501 nm to 600 nm and less than 1% visible over 601 nm to 700 nm, and therefore has an average transparency of less than 5% over the portion of visible light in the range of 501 nm to 700 nm.

In some embodiments, a structure of the second sub-pixel of the first pixel of the device may be configured to be a cavity sub-pixel, a plasmonic sub-pixel, and/or a non-transparent Lambertian sub-pixel (e.g., a Lambertian sub-pixel that is less than 10% transparent for any wavelength in the visible spectrum). A non-transparent sub-pixel is one where the transparency is less than 10% for at least a portion of the wavelength in the wavelength spectrum (e.g., 400 nm to 1500 nm, 400 nm to 700 nm, or the like).

In an embodiment, a sub-pixel having an emission profile of Lambertian or near-Lambertian may be formed when one electrode is reflective (non-transparent) and the other electrode is transparent which allows light to exit the device on the transparent electrode side. In an embodiment, an emission profile of Lambertian or near-Lambertian may maintain an emission intensity within 20% of emission intensity at the normal direction, when viewing at an angle of normal +/−45° from normal. In an embodiment, the Lambertian sub-pixel may be formed with no cavity within the sub-pixel or with a weak cavity within the sub-pixel. When the second sub-pixel of the first pixel is configured as the plasmonic sub-pixel, the second sub-pixel may be further configured to output red light, yellow light, and/or green light. Alternatively, when the second sub-pixel of the first pixel is configured as the plasmonic sub-pixel, the second sub-pixel may be further configured to output blue light and/or deep blue light. When second sub-pixel of the first pixel is configured as the cavity sub-pixel, the second sub-pixel may be further configured to output light blue light, deep blue light, red light, and/or green light.

A structure of at least the second sub-pixel of the first pixel of the device may be a cavity sub-pixel, and the first sub-pixel of the first pixel may be disposed over at least a portion of one or more sensors, and/or at least a portion of one or more cameras.

In some embodiments, the first sub-pixel of the first pixel may be configured to output light having a first color at a first resolution, and the second sub-pixel of the first pixel may be configured to output light having a second color at a second resolution. The first sub-pixel of the first pixel may be configured to output light having a first color at a first fill-factor, and the second sub-pixel of the first pixel may be configured to output light having a second color at a second fill-factor.

In some embodiments, the device shown in FIGS. 3-12 may include at least one color altering layer disposed over at least a portion of the first sub-pixel and/or the second sub-pixel of the first pixel.

In some embodiments, a first set of pixels of the one or more pixels of the device may have a first resolution, and a second set of pixels of the one or more pixels may have a second resolution. In some embodiments, a first set of pixels of the one or more pixels may have a first fill-factor, and a second set of pixels of the one or more pixels may have a second fill-factor.

In some embodiments, a first set of pixels of the one or more pixels may have a first transparency, and a second set of pixels of the one or more pixels may have a second transparency.

In some embodiments, the first sub-pixel of the first pixel may be at least 5%, 10%, 20%, 30%, 40%, or 50% larger in area on the device relative to the second sub-pixel of the first pixel. In alternative embodiments, the second sub-pixel of the first pixel may be at least 5%, 10%, 20%, 30%, 40%, or 50% larger in area on the device relative to the first sub-pixel. For example, the first sub-pixel, which is transparent, may have a larger area than the second sub-pixel which is non-transparent. In another example, the first sub-pixel of the first pixel may emit a “blue” light and may be larger area than the second sub-pixel of the first pixel which may emit a “green” or “red” light. Alternatively, the opposite may occur, where the non-transparent sub-pixel is larger than the transparent sub-pixel and/or the “green” or “red” light sub-pixel may be larger than the “blue” light sub-pixel.

In some embodiments, at least one sub-pixel of the device (e.g., the first sub-pixel of the first pixel and/or the second sub-pixel of the first pixel) may be a stacked device. At least one sub-pixel (e.g., the first sub-pixel of the first pixel and/or the second sub-pixel of the first pixel) of the device may be a tandem sub-pixel comprising two or more emissive layers with a charge generation layer between a first emissive layer of the two or more emissive layers and a second emissive layer of the two or more layers. As used throughout, “between” may not necessarily mean that the first emissive layer and the second emissive layer are directly adjacent to a charge generation layer (CGL).

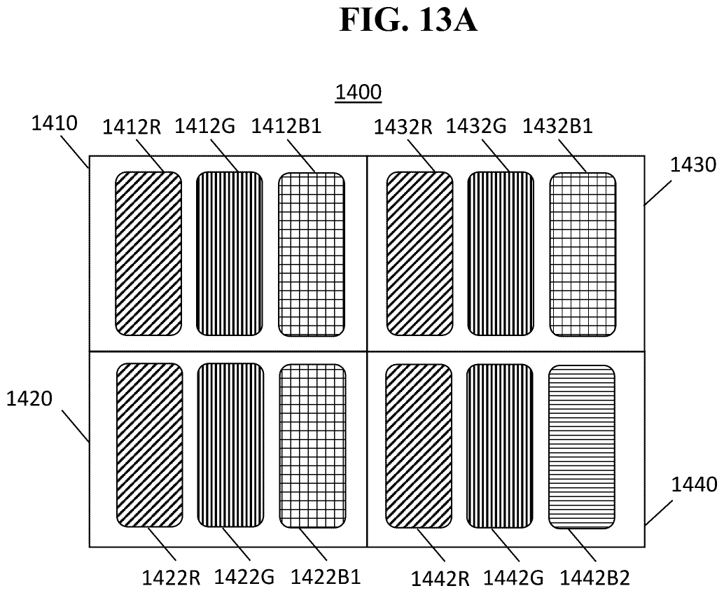

In an embodiment, the more transparent region of the display may be driven as a passive matrix display so as to remove most of the transistors from the backplane in this region compared to active drive techniques. As most sub-pixel circuits to drive OLEDs have multiple TFT circuits often using six or seven or even more TFTs, and there are at least 3 sub-pixels per pixel, using one or no TFT passive matrix approach per sub-pixel could save nearly 20 TFTs per pixel which will significantly improve display transparency. Such an arrangement can be reasonably implemented in a small local region of the display, for example as shown in FIG. 12. A TFT is a thin film transistor made by depositing thin film active layers with subsequent device processing. The active layers may be based on amorphous silicon, poly-Silicon, semiconducting oxides, nanotubes or other known TFT approaches.

Passive matrix addressing works by selecting a pixel using scan lines, assuming N scan lines, and driving each subpixel with a current N times the current it would require for steady-state operation as in active matrix addressing, for just the period that the subpixel is being addressed. So the overall time averaged brightness to the eye is the same as in an active matrix display, but the OLEDs are effectively being pulsed at least N times the current for 1/N period of time. Typically, such an arrangement can be implemented for small size displays with about 200 or fewer scan lines, as this passive matrix architecture is much less power efficient than an active matrix drive.

In a conventional passive matrix display each OLED subpixel is addressed by using a row/scan line on one side of the OLED and a patterned cathode (in stripes or lines) on the other side. In an active matrix display the cathode is usually electrically continuous across the display, with no patterning. In an embodiment as disclosed herein, an addressing scheme may be used in which one TFT in each subpixel is used as the addressing element for each OLED in conjunction with an unpatterned electrically continuous cathode. In this case the OLED will be current driven while the subpixel is addressed. Such arrangements are disclosed, for example, in U.S. patent application Ser. No. 17/452,135 (U.S. Pat. Publn. No. 2022/01390946), the entire contents of which is incorporated herein by reference.

To avoid the number of scan lines N for the passive matrix region being too high, a separate driving scheme may be used for only the small passive matrix (PM) transparent region, using a dedicated current driven data chip and a second PM scan driver. The scan driver may be integrated into the display and a small second current data driver chip to provide PM data drivers can be placed on, or attached to, the display substrate near to the transparent region, as shown in FIG. 12. This approach uses a relatively low N. For example, if a cell phone has a 500 dpi resolution and the region over the camera is about 5 mm (0.2 in), the region includes 100 pixels and therefore N=100 for the region.

The PM and active matrix (AM) sections of the display require different drive signals from the two different driver chips because the AM portion generally is voltage driven, while PM pixels generally are current driven. As shown in FIG. 12, the PM region may be disposed over the optical components at one corner of the overall display. This allows the PM region to be directly connected to the associated dedicated data chip and scan drivers. The data lines and scan lines driving the AM portion of the rest of the display may terminate at the edge of the PM region.

If the PM region, or a portion of the PM region corresponding to the location of a camera or other sensor, is not placed in one of the display corners, but more in the center of the display, then additional data and scanlines may be used to connect the PM pixels to their dedicated PM scan driver and PM data drivers, while allowing the existing AM data and scan signals to propagate through the display to AM pixels to be driven on the other side of the PM display region away from the scan and data drivers.

In an active-matrix or AM display, each sub-pixel may be attached to a transistor and usually a capacitor that actively maintain the sub-pixel state or drive current while other sub-pixels are being addressed. This is in contrast with the passive matrix technology, where each sub-pixel is only driven when its scan line is being addressed.

That is, in an embodiment, at least the first sub-pixel of the first pixel of the one or more pixels may be configured for passive matrix addressing. In an embodiment, at least the first sub-pixel of the first pixel of the one or more pixels may be configured for active matrix addressing.

The device may include a third sub-pixel of the first pixel. The third sub-pixel may be greater than 30%, greater than 40%, greater than 50%, greater than 60%, greater than 70%, greater than 80%, and/or greater than 90% transparent across the portion of the wavelength spectrum. In an embodiment, the portion of the wavelength spectrum may be in the range of 400 nm to 1500 nm. In an embodiment, the portion of wavelength spectrum may be in the range of 400 nm to 700 nm. In an embodiment, the third sub-pixel may be configured to emit green light or yellow light. In an embodiment, the third sub-pixel of the first pixel may be less than 10%, less than 9%, less than 8%, less than 7%, less than 6%, less than 5%, less than 4%, less than 3%, less than 2%, and/or less than 1% transparent across the portion of the wavelength spectrum. That is, the third sub-pixel of the first pixel may be transparent, or the third sub-pixel of the first pixel may be non-transparent. In an embodiment, the third sub-pixel of the first pixel may be a transparent sub-pixel, a non-transparent sub-pixel, a cavity sub-pixel, a plasmonic sub-pixel, and/or a Lambertian sub-pixel.

For example, as shown in FIG. 3, the third sub-pixel may be sub-pixel 303 or 305. In FIG. 4, the third sub-pixel may be sub-pixel 401 or sub-pixel 403. In FIG. 5, the third sub-pixel may be sub-pixel 503 or 505. In FIG. 6, the third sub-pixel may be sub-pixel 601 or 603. In FIG. 7, the third sub-pixel may be sub-pixel 601 or 603. In FIG. 8, the third sub-pixel may be sub-pixel groups 703 or 705. In FIG. 9, the third sub-pixel may be sub-pixel group 801 or 803. In FIG. 10, the third sub-pixel may be sub-pixel group 903 or 905. In FIG. 11, the third sub-pixel may be sub-pixel group 1001 or 1003. In some embodiments, the third sub-pixel may be a transparent sub-pixel, a non-transparent sub-pixel, a cavity sub-pixel, and/or a plasmonic sub-pixel.

An overall color gamut for the device shown in FIGS. 3-12 may be greater than 90% of DCI-P3 color space, greater than 95% of DCI-P3 color space, greater than 90% of Adobe™ RGB color space, and/or greater than 90% of BT.2020 color space. The device may have an overall transparency that greater than 30%, greater than 40%, greater than 50%, greater than 60%, greater than 70%, and/or greater than 80% of a portion of the wavelength spectrum to pass through the one or more pixels of the device. In an embodiment, the portion of the wavelength spectrum may be in the range of 400 nm to 1500 nm. In an embodiment, the portion of wavelength spectrum may be in the range of 400 nm to 700 nm. In an embodiment, the portion of the wavelength spectrum may be in the range of 450 nm to 650 nm. In an embodiment, the portion of the wavelength spectrum may be in the range of 500 nm to 650 nm. In an embodiment, the portion of the wavelength spectrum may be in the range of two sub-groups of wavelength ranges of visible light. For example, a first sub-group may be 500 nm to 550 nm and the second sub-group may be 600 nm to 650 nm. In an embodiment, the transparency of the first sub-pixel may be configured to allow greater than 30%, greater than 40%, greater than 50%, greater than 60%, greater than 70%, greater than 80%, and/or greater than 90% as an average transparency over at least a portion of the wavelength spectrum. For example, the sub-pixel may be greater than 90% transparent over 501 nm to 600 nm and greater than 10% transparent over 601 nm to 700 nm, and therefore has an average transparency of greater than 50% over the portion of the wavelength spectrum in the range of 501 nm to 700 nm. The transparency of the device may be represented by a line perpendicularly disposed though the first sub-pixel of the first pixel or the second sub-pixel of the first pixel may be greater than 30%, greater than 40%, greater than 50%, greater than 60%, greater than 70%, and/or greater than 80%.

The device shown in FIGS. 3-12 may have a regional transparency of at least one pixel of the one or more pixels. For example, the regional transparency of the first pixel may be configured to be greater than 30%, greater than 40%, greater than 50%, greater than 60%, greater than 70%, greater than 80%, and/or greater than 90%, of a portion of the wavelength spectrum to pass through the first pixel.

In an embodiment, the device may include one or more sensors, where at least a portion of the first pixel is disposed over at least a portion of the one or more sensors, and/or the device may include one or more cameras, where at least a portion of the first pixel is disposed over at least a portion of the one or more cameras.

In an embodiment, one or more sensors of the device may be configured to receive a first wavelength range, where the first sub-pixel of the first pixel may be disposed over at least a portion of a sensor of the one or more sensors, and the first sub-pixel of the first pixel may be at least 30% transparent over at least a portion of the first wavelength range.

In an embodiment, the first sub-pixel of the first pixel is configured to output light having a first color at a first resolution, and the second sub-pixel of the first pixel is configured to output light having a second color at a second resolution.

In an embodiment, the first sub-pixel of the first pixel may be configured to output light having a first color at a first fill-factor, and the second sub-pixel of the first pixel may be configured to output light having a second color at a second fill-factor. The fill-factor is a measure of how much of the area of a given sub-pixel or pixel can actively emit light through electrical excitation.

In an embodiment, the one or more pixels of the device may include a first set of pixels and a second set of pixels. The first set of pixels may include the first pixel of the device, where the second set of pixels does not include the first pixel. The first set of pixels may include a first resolution and the second set of pixels has a second resolution.

In an embodiment, the one or more pixels of the device may include a first set of pixels and a second set of pixels. The first set of pixels may include the first pixel, and the second set of pixels does not include the first pixel. The first set of pixels may have a first fill-factor and the second set of pixels may have a second fill-factor.

In an embodiment, the one or more pixels of the device may include a first set of pixels. The first set of pixels may include the first pixel. The device may include a second set of pixels of the one or more pixels, where the second set of pixels does not include the first pixel. The first set of pixels may have a first transparency, and the second set of pixels may have a second transparency.

In an embodiment, the first sub-pixel of the first pixel of the device may have a first area, and the second sub-pixel of the first pixel may have a second area. The first area may be larger on the device than the second area by 5%, 10%, 20%, 30%, 40%, and/or 50%.

In an embodiment, the first sub-pixel of the first pixel of the device may have a first area, and the second sub-pixel of the first pixel may have a second area. The second area may be larger on the device than the first area by 5%, 10%, 20%, 30%, 40%, and/or 50%.

In an embodiment, one pixel of the one or more pixels of the device may include an emissive layer having a fluorescent material, a phosphorescent material, a thermally activated delayed fluorescent (TADF) material, and quantum dots. In an embodiment, each pixel of the one or more pixels of the device may include an emissive layer having a fluorescent material, a phosphorescent material, a thermally activated delayed fluorescent (TADF) material, and/or quantum dots.

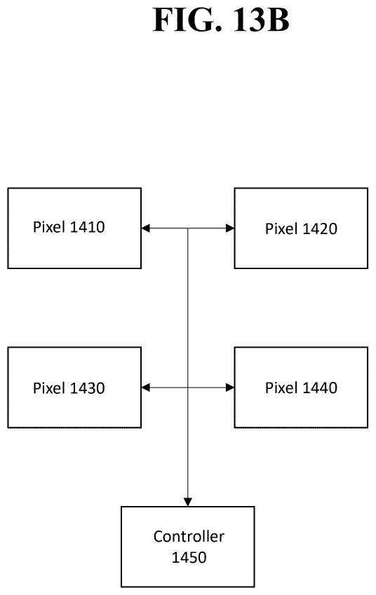

FIG. 13A shows an example of a layout for a RGB1B2 (red, green, light blue, deep blue) display where each deep blue (B2) cavity or plasmonic sub-pixel may be shared amongst 4 pixels, and the other 3 blue sub-pixels may be transparent according to embodiments of the disclosed subject matter. It should be noted, while FIG. 13A shows a B1B2 architecture, embodiments of the present invention recognize that any of the colors may be in a dual architecture, in other words there may be two reds, two greens, or two blue colors rendered in the display in different pixels. Here, one of the reds may be light red and one may be deep red. Additionally, one of the greens may be light green and one may be deep green. Embodiments of the present invention recognize, similar to the advantages described above and blue as they related to blue (i.e. B1/B2) may be similar for green and red or any other color in a light/dark dual sub-pixel configuration.

The layout 1400 may include a first pixel 1410, a second pixel 1420, a third pixel 1430, and a fourth pixel 1440. The first pixel 1410 may include red sub-pixel 1412R configured to emit red light, green sub-pixel 1412G configured to emit green light, and light blue sub-pixel 1412B1 configured to emit light blue light. The second pixel 1420 may include red sub-pixel 1422R configured to emit red light, green sub-pixel 1422G configured to emit green light, and light blue sub-pixel 1422B1 configured to emit light blue light. The third pixel 1430 may include red sub-pixel 1432R configured to emit red light, green sub-pixel 1432G configured to emit green light, and light blue sub-pixel 1432B1 configured to emit light blue light. The fourth pixel 1140 may include red sub-pixel 1442R configured to emit red light, green sub-pixel 1442G configured to emit green light, and deep blue sub-pixel 1442B2 configured to emit deep blue light.

In the layout 1400, where the deep blue sub-pixel 1442B2 of the fourth pixel may be a cavity sub-pixel or may be a plasmonic sub-pixel. The deep blue sub-pixel 1442B2 may be shared amongst the first pixel 1410, the second pixel 1420, the third pixel 1430, and the fourth pixel 1440. The light blue sub-pixels 1410, 1420, and/or 1430 may be transparent according to embodiments of the disclosed subject matter.

For example, in the layout 1400 shown in FIGS. 13A-13B, the red sub-pixel 1442R and/or the green sub-pixel 1442G of pixel 1440 may be at least 30% transparent, and the deep blue sub-pixel 1442B2 may be less than 10% transparent. The red sub-pixel 1412R, 1422R, and/or 1432R, and the green sub-pixel pixel 1412G, 1422G, and/or 1432G may be at least 30% transparent.

FIG. 13B shows a controller 1450 that may be configured to control the operation of pixels 1410, 1420, 1430, and 1440 shown in detail in FIG. 13A. In an embodiment, the controller 1450 may be configured to individual control one or more sub-pixels of the pixels 1410, 1420, 1430, and/or 1440 shown in FIG. 13A.

In an embodiment, the controller 1450 may be configured to activate both a deep blue sub-pixel (e.g., deep blue sub-pixel 1442B2) and a light blue sub-pixel (e.g., light blue sub-pixel 1412B1, 1422B1, or 1432B1) to emit blue light that is not deeper than blue light generated by an emissive material in the light blue sub-pixel. The controller may activate only the deep blue sub-pixel (rather than both the deep blue and light blue sub-pixels) to emit blue light that is deeper than blue light generated by the emissive material of in the light blue sub-pixel.

In an embodiment similar to or the same as that shown in FIGS. 13A-13B, the device may include one or more pixels. A first pixel of the one or more pixels may include a first sub-pixel and a second sub-pixel. The first sub-pixel of the first pixel (e.g., a red sub-pixel) may at least 30% transparent across a portion of a wavelength spectrum. In an embodiment, the wavelength spectrum may be from 400 nm to 1500 nm. In an embodiment, the wavelength spectrum may be 400 nm to 700 nm, or may be 700 nm to 1500 nm. The second sub-pixel (e.g., a blue sub pixel) of the first pixel is less than 10% transparent across the portion of the wavelength spectrum. The device may include a second pixel of the one or more pixels. This second pixel may have a first sub-pixel that is at least 30% transparent.

In an embodiment, the first sub-pixel of the first pixel of the device may be configured to emit a first color light, the second sub-pixel of the first pixel of the device may be configured to emit a second color light, and the first sub-pixel of the second pixel may be configured to emit a third color light. In an embodiment, the first color light may be yellow, cyan, green, or red. The second color light may be deep blue light, and the third color light may be light blue light or cyan light.

In an embodiment, the first sub-pixel of the first pixel of the device may have a first emissive material, and the first sub-pixel of the second pixel of the device may have a second emissive material. The first emissive material and the second emissive material may be the same material. Alternatively, the first emissive material and the second emissive material may be different materials.

In an embodiment, the first pixel of the device may include a third sub-pixel which may be at least 30% transparent across the portion of the wavelength spectrum. This third sub-pixel of the first pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is at least 30% transparent. The embodiment may include a second pixel of the device that has a first sub-pixel that is at least 30% transparent.

In an embodiment, the third sub-pixel of the first pixel of the device may be less than 10% transparent across the portion of the wavelength spectrum. In this arrangement, the third sub-pixel of the first pixel of the device may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is less than 10% transparent. The embodiment may include a second pixel of the device that has a first sub-pixel that is at least 30% transparent.

In an embodiment, the second pixel of the device may include a second sub-pixel that is at least 30% transparent across the portion of the wavelength spectrum. In this arrangement, the second sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is at least 30% transparent. The embodiment may include a second pixel of the device that has a first sub-pixel that is at least 30% transparent and the second sub-pixel that is at least 30% transparent.

In an embodiment, the second pixel of the device may include a second sub-pixel that is less than 10% transparent across the portion of the wavelength spectrum. The second sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is at least 30% transparent. The embodiment includes a second pixel of the device that has a first sub-pixel that is at least 30% transparent and the second sub-pixel that is less than 10% transparent.

In an embodiment, the second pixel of the device may include a second sub-pixel that is at least 30% transparent across the portion of the wavelength spectrum. The second sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is less than 10% transparent. The embodiment includes a second pixel of the device that has a first sub-pixel that is at least 30% transparent and the second sub-pixel that is at least 30% transparent.

In an embodiment, the second pixel of the device may include a second sub-pixel that may be less than 10% transparent across the portion of the wavelength spectrum. The second sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is less than 10% transparent. The embodiment includes a second pixel that may have a first sub-pixel that is at least 30% transparent and the second sub-pixel that is less than 10% transparent.

In an embodiment, the second pixel of the device may include a third sub-pixel that is at least 30% transparent across the portion of the wavelength spectrum. The third sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is at least 30% transparent. The embodiment includes a second pixel of the device that may have a first sub-pixel that is at least 30% transparent, a second sub-pixel that is that is at least 30% transparent, and the third sub-pixel that is at least 30% transparent.

In an embodiment, the second pixel of the device may include a third sub-pixel that is less than 10% transparent across the portion of the wavelength spectrum. The third sub-pixel of the second pixel may be configured to emit yellow light, cyan light, green light, or red light. In this embodiment, the first pixel may include the first, second, and third sub-pixels, where the first sub-pixel is at least 30% transparent, the second sub-pixel is less than 10% transparent, and the third sub-pixel is at least 30% transparent. The embodiment includes a second pixel of the device that may have a first sub-pixel that is at least 30% transparent, a second sub-pixel that is that is at least 30% transparent, and the third sub-pixel that is less than 10% transparent.

In an embodiment, the second pixel of the device may include a third sub-pixel that is less than 10% transparent across the portion of the wavelength spectrum. The third sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is at least 30% transparent. The embodiment includes a second pixel of the device that may have a first sub-pixel that is at least 30% transparent, a second sub-pixel that is that is less than 10% transparent, and the third sub-pixel that is less than 10% transparent.

In an embodiment, the second pixel of the device may include a third sub-pixel that is at least 30% transparent across the portion of the wavelength spectrum. The third sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is at least 30% transparent. The embodiment includes a second pixel of the device that may have a first sub-pixel that is at least 30% transparent, a second sub-pixel that is that is at least 30% transparent, and the third sub-pixel that is at least 30% transparent.

In an embodiment, the second pixel of the device may include a third sub-pixel that is less than 10% transparent across the portion of the wavelength spectrum. The third sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is less than 10% transparent. The embodiment includes a second pixel of the device that may have a first sub-pixel that is at least 30% transparent, a second sub-pixel that is that is at least 30% transparent, and the third sub-pixel that is less than 10% transparent.

In embodiment, the second pixel of the device may include a third sub-pixel that is less than 10% transparent across the portion of the wavelength spectrum. The third sub-pixel of the second pixel may be configured to emit yellow light, cyan light, green light, or red light. In this embodiment, the first pixel of the device may include the first, second, and third sub-pixels, where the first sub-pixel is at least 30% transparent, the second sub-pixel is less than 10% transparent, and the third sub-pixel is less than 10% transparent. The embodiment includes a second pixel of the device that may have a first sub-pixel that is at least 30% transparent, a second sub-pixel that is that is less than 10% transparent, and the third sub-pixel that is less than 10% transparent.

For each first pixel of the device, there may be at least N second pixels, where N may be N≥2, N≥4, or N≥16. In some embodiments, N may be an even integer.

In an embodiment, the second sub-pixel of the first pixel of the device may have a first area, and the first area may be 60% or less of a total area of the first pixel.

In embodiment, the deep blue light and the light blue light may have 1931 CIE y coordinates that differ by an amount that is at least 0.02, at least 0.04, and/or at least 0.08.

In an embodiment, the deep blue light may have a CIE y coordinate range of y≤0.15, and the light blue light may have a 1931 CIE y coordinate range of y>0.15.

In an embodiment, the deep blue light may have a CIE y coordinate range of y≤0.10 and the light blue light may have a 1931 CIE y coordinate range of y>0.10.

In an embodiment, the second sub-pixel of the first pixel of the device may be a plasmonic sub-pixel or a cavity sub-pixel.

In an embodiment, a total number of sub-pixels that may be configured to emit deep blue light in the device plus a total number of sub-pixels that may be configured to emit light blue light in the device may be equal to a total number of pixels in the device.

In an embodiment, the first sub-pixel of the first pixel and the first sub-pixel of the second pixel of the device may be disposed over at least a portion of one or more sensors, and/or at least a portion of one or more cameras.

In an embodiment, the first sub-pixel of the first pixel and the first sub-pixel of the second pixel of the device may be disposed over a sensor and configured to allow a range of wavelengths of light to be transmitted for which a sensor is configured for.

In an embodiment, a controller may be communicatively coupled to the one or more pixels of the device. The controller may activate both the second sub-pixel of the first pixel and the first sub-pixel of the second pixel to emit blue light that is not deeper than blue light generated by an emissive material in the second sub-pixel of the first pixel. The controller may be configured to activate only the second sub-pixel of the first pixel out of the second sub-pixel of the first pixel and the first sub-pixel of the second pixel to emit blue light that is deeper than blue light generated by the emissive material in the first sub-pixel of the second pixel.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
one or more pixels, a first pixel of the one or more pixels comprising:
a first sub-pixel; and
a second sub-pixel,
wherein the first sub-pixel of the first pixel is at least 30% transparent across a portion of a wavelength spectrum, wherein the wavelength spectrum is from 400 nm to 1500 nm, and
wherein the second sub-pixel of the first pixel is less than 10% transparent across the portion of the wavelength spectrum.

2. The device of claim 1, further comprising a second pixel of the one or more pixels, wherein the second pixel comprises a first sub-pixel, wherein the first sub-pixel of the second pixel is at least 30% transparent,
wherein the first sub-pixel of the first pixel emits a first color light, wherein the second sub-pixel of the first pixel emits a second color light, and wherein the first sub-pixel of the second pixel emits a third color light, wherein the first color light is selected from the group consisting of: yellow, cyan, green and red, wherein the second color light is deep blue light, and wherein the third color light is light blue light.

3. The device of claim 1, wherein the first pixel further comprises a third sub-pixel.

4. The device of claim 3, wherein at least one of the following conditions (i) and (ii) is true:
(i) a transparency of the third sub-pixel of the first pixel is configured to allow greater than 30% of the portion of the wavelength spectrum pass through the third sub-pixel of the first pixel;
(ii) a transparency of the third sub-pixel of the first pixel is configured to allow less than 10% of the portion of the wavelength spectrum to pass through the third sub-pixel of the first pixel.

5.-35. (canceled)

36. The device of claim 1, wherein the second sub-pixel of the first pixel is configured to be at least one selected from the group consisting of: a cavity sub-pixel, a plasmonic sub-pixel, and a Lambertian sub-pixel.

37.-39. (canceled)

40. The device of claim 1, wherein an overall color gamut for the device is at least one selected from a group consisting of: greater than 90% of DCI-P3 color space, greater than 95% of DCI-P3, greater than 80% of Adobe™ RGB color space, and greater than 90% of BT.2020 color space.

41.-63. (canceled)

64. The device of claim 1, further comprising one or more sensors configured to receive a first wavelength range, wherein the first sub-pixel is disposed over at least a portion of a sensor of the one or more sensors, and wherein the first sub-pixel is at least 30% transparent over at least a portion of the first wavelength range.

65.-83.

84. The device of claim 1, wherein at least one of the first sub-pixel or the second sub-pixel is a tandem sub-pixel, wherein the tandem sub-pixel comprises two or more emissive layers and a charge generation layer, wherein the charge generation layer is disposed between a first emissive layer of the two or more emissive layers and a second emissive layer of the two or more emissive layers.

85.-86. (canceled)

87. The device of claim 1, wherein one pixel of the one or more pixels comprises an emissive layer having at least one selected from the group consisting of: a fluorescent material, a phosphorescent material, a thermally activated delayed fluorescent (TADF) material, and quantum dots.

88. (canceled)

89. The device of claim 2, wherein the first sub-pixel of the first pixel comprises a first emissive material and wherein the first sub-pixel of the second pixel comprises a second emissive material.

90. The device of claim 89, wherein the first emissive material and the second emissive material are the same material.

91. The device of claim 89, wherein the first emissive material and the second emissive material are different material.

92.-103. (canceled)

104. The device of claim 2, wherein for each first pixel there are at least N second pixels, wherein N is selected from the group consisting of: N≥2, N≥4, and N≥16.

105.-107. (canceled)

108. The device of claim 2, wherein the second color light and the third color light have 1931 CIE y coordinates that differ by at least 0.02.

109.-110. (canceled)

111. The device of claim 2, wherein at least one of the following conditions (i) and (ii) is true:
(i) the second color light has a CIE y coordinate range of y≤0.15 and wherein the third color light has a 1931 CIE y coordinate range of y>0.15;
(ii) the second color light has a CIE y coordinate range of y<0.10 and wherein the third color light has a 1931 CIE y coordinate range of y>0.10.

112.-114. (canceled)

115. The device of claim 1, wherein the first sub-pixel of the first pixel is disposed over at least one selected from a group consisting of: at least a portion of one or more sensors, and at least a portion of one or more cameras.

116.-119. (canceled)

120. The device of claim 1, wherein each pixel of the one or more pixels comprises three sub-pixels.

121. The device of claim 1, wherein each pixel of the one or more pixels comprises four or more sub-pixels.

122.-125. (canceled)

126. A consumer electronic device comprising:
one or more pixels, a first pixel of the one or more pixels comprising:
a first sub-pixel; and
a second sub-pixel,
wherein the first sub-pixel of the first pixel is at least 30% transparent across a portion of a wavelength spectrum, wherein the wavelength spectrum is from 400 nm to 1500 nm, and
wherein the second sub-pixel of the first pixel is less than 10% transparent across the portion of the wavelength spectrum; and
a second pixel of the one or more pixels, wherein the second pixel comprises a first sub-pixel, wherein the first sub-pixel of the second pixel is at least 30% transparent,
wherein the first sub-pixel of the first pixel emits a first color light, wherein the second sub-pixel of the first pixel emits a second color light, and wherein the first sub-pixel of the second pixel emits a third color light, wherein the first color light is selected from the group consisting of: yellow, cyan, green and red, wherein the second color light is deep blue light, and wherein the third color light is light blue light.

127. The consumer electronic device of claim 126, wherein the consumer electronic device that is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, optical communication device, and a sign.
